(19) United States
(12) Patent Application Publication
(10) Pub. No.: US 2021/0028101 A1
(43) Pub. Date: Jan. 28, 2021

(54) EMBEDDED PATCH FOR LOCAL MATERIAL PROPERTY MODULATION

(71) Applicant: Intel Corporation, Santa Clara, CA (US)

(72) Inventors: Bai NIE, Chandler, AZ (US); Haobo CHEN, Gilbert, AZ (US); Gang DUAN, Chandler, AZ (US); Brandon C. MARIN, Chandler, AZ (US); Srinivas PIETAMBARAM, Chandler, AZ (US)

(21) Appl. No.: 16/522,483

(22) Filed: Jul. 25, 2019

(51) Int. Cl. H01L 23/498; H01L 23/66; H01L 21/48

(52) U.S. Cl. CPC H01L 23/49838; H01L 23/49822; H01L 2223/6616; H01L 21/485; H01L 23/66

(57) ABSTRACT

Embodiments disclosed herein include electronic packages and methods of making such packages. In an embodiment, a package substrate comprises a substrate comprising a first dielectric material, a first trace embedded in the substrate, and a patch in direct contact with the first trace. In an embodiment, the patch comprises a second dielectric material that is different than the first dielectric material.

### TECHNICAL FIELD

Embodiments of the present disclosure relate to semiconductor devices, and more particularly to electronic packages with embedded patches to provide local property modulation.

### BACKGROUND

In server applications, power loss in the package substrate is becoming ever more critical, particularly for long signal routing lines. Insertion loss (which includes conductor loss and dielectric loss) can be significant sources of power loss in the system. Low loss tangent dielectric material may reduce dielectric losses. Conductor losses may be reduced by increasing the width of the trace. However, in order to maintain proper impedance matching, the dielectric material thickness above and below the traces needs to be increased for wider trace (assuming there is no change in the dielectric constant (Dk)).

The increase in dielectric thickness results in several challenges for substrate manufacturing. For example, it is more difficult to form vias in thicker dielectrics. Additionally, copper plating uniformity becomes problematic when skip layer techniques are used to increase the dielectric thicknesses. Skip layer architectures also result in CTV (chip area thickness variation) and/or BTV (bump top variation) control issues as well as lamination undulation.

Currently used dielectric material in server substrate applications are buildup films that have high filler content to enable low loss tangent and provide improved coefficient of thermal expansion (CTE) matching. However, the fillers (e.g., SiO₂) have a dielectric constant around 4.0 which limits the possible reductions in the dielectric constant of the overall material. Furthermore, it is not easy to produce a low-k dielectric material while maintaining the other properties (e.g., mechanical properties, thermal properties, etc.) of currently used dielectric materials. As such, it is not currently practical to replace an entire layer of a package substrate with a low loss tangent, low dielectric constant material.

### BRIEF DESCRIPTION OF THE DRAWINGS

FIG. 1A is a perspective view illustration of a package substrate that comprises a patch around a trace that is embedded in the package substrate, in accordance with an embodiment.

FIG. 1B is a cross-sectional illustration of a package substrate that comprises a patch that surrounds a trace, in accordance with an embodiment.

FIG. 2A is a cross-sectional illustration of a package substrate with a first plurality of traces embedded in a patch and a second plurality of traces that are embedded in a first dielectric layer, in accordance with an embodiment.

FIG. 2B is a cross-sectional illustration of a package substrate with a first plurality of traces that are each embedded in a different patch and a second plurality of traces that are embedded in a first dielectric layer, in accordance with an embodiment.

FIG. 2C is a cross-sectional illustration of a package substrate with a patch that passes through a plurality of layers of the package substrate, in accordance with an embodiment.

FIG. 2D is a cross-sectional illustration of a package substrate with a first patch in a first layer and a second patch in a second layer, in accordance with an embodiment.

FIG. 2E is a cross-sectional illustration of a package substrate with a patch around a trace in a microstrip configuration, in accordance with an embodiment.

FIG. 2F is a cross-sectional illustration of a package substrate with a patch around a trace in an embedded microstrip configuration, in accordance with an embodiment.

FIG. 3A is a cross-sectional illustration of an electronic package with a first metal layer in a first dielectric layer, in accordance with an embodiment.

FIG. 3B is a cross-sectional illustration of the electronic package after a first opening is formed into the first dielectric layer to expose a portion of the first metal layer, in accordance with an embodiment.

FIG. 3C is a cross-sectional illustration of the electronic package after a first patch layer is disposed in the first opening and over the first dielectric layer, in accordance with an embodiment.

FIG. 3D is a cross-sectional illustration of the electronic package after the first patch layer is recessed, in accordance with an embodiment.

FIG. 3E is a cross-sectional illustration of the electronic package after a seed layer is disposed over the first dielectric layer and the first patch layer, in accordance with an embodiment.

FIG. 3F is a cross-sectional illustration of the electronic package after a resist layer is disposed over the seed layer, in accordance with an embodiment.

FIG. 3G is a cross-sectional illustration of the electronic package after the resist layer is patterned, in accordance with an embodiment.

FIG. 3H is a cross-sectional illustration of the electronic package after a trace is disposed in the openings through the resist layer, in accordance with an embodiment.

FIG. 3I is a cross-sectional illustration of the electronic package after the resist layer and exposed portions of the seed layer are removed, in accordance with an embodiment.

FIG. 3J is a cross-sectional illustration of the electronic package after a second dielectric layer is disposed over the trace, in accordance with an embodiment.

FIG. 3K is a cross-sectional illustration of the electronic package after a second opening is formed through the second dielectric layer to expose the trace, in accordance with an embodiment.

FIG. 3L is a cross-sectional illustration of the electronic package after a second patch layer is disposed in the second opening and over the second dielectric layer, in accordance with an embodiment.

FIG. 3M is a cross-sectional illustration of the electronic package after the second patch layer is recessed, in accordance with an embodiment.

FIG. 3N is a cross-sectional illustration of the electronic package after a second metal layer is disposed over the second patch layer, in accordance with an embodiment.

FIG. 4 is a cross-sectional illustration of an electronic system that comprises a package substrate with one or more patches surrounding traces, in accordance with an embodiment.

FIG. 5 is a schematic of a computing device built in accordance with an embodiment.

### EMBODIMENTS OF THE PRESENT DISCLOSURE

Described herein are electronic packages that comprise embedded patches to provide local property modulation, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, server applications and other high performance computing (HPC) applications suffer from power losses over transmission lines through the package substrate. Particularly, conductor losses and dielectric losses contribute to the insertion loss of a transmission line. The transmission lines have been formed wider in order reduce conductor losses. However, wider transmission lines will change the impedance of the transmission line when no other changes are made to the surrounding dielectric materials. Accordingly, increases to the dielectric thickness have been proposed to counteract the changes to the impedance caused by wider transmission lines. Unfortunately, increasing the thickness of the dielectric between metal layers results in many drawbacks, such as those described above (e.g., CTV/BTV control issues, lamination undulation, copper plating uniformity, and the like).

Accordingly, embodiments disclosed herein include localized modulation of the dielectric properties proximate to the transmission lines. That is, the transmission line is embedded in a patch comprising a dielectric material that is different than the dielectric material of the package substrate. This allows for one or more properties of the surrounding dielectric to be optimized for low loss transmission, without compromising the material properties of the package substrate globally. Furthermore, the ability to tailor the dielectric properties of the patch material allows for impedance matching to be implemented without the need for increasing dielectric thickness. That is, wide transmission lines that reduce conductor losses may be provided without also needing to increase the dielectric thickness.

In a particular embodiment, the patch that surrounds the transmission line is optimized to have a low dielectric constant (Dk) and low loss tangent (Df) in order to reduce the insertion losses. However, it is to be appreciated that the use of a patch surrounding features within a package substrate may also be used to locally modulate other properties. For example, the patch may be used to locally modulate mechanical properties, electrical properties, thermal properties, or the like.

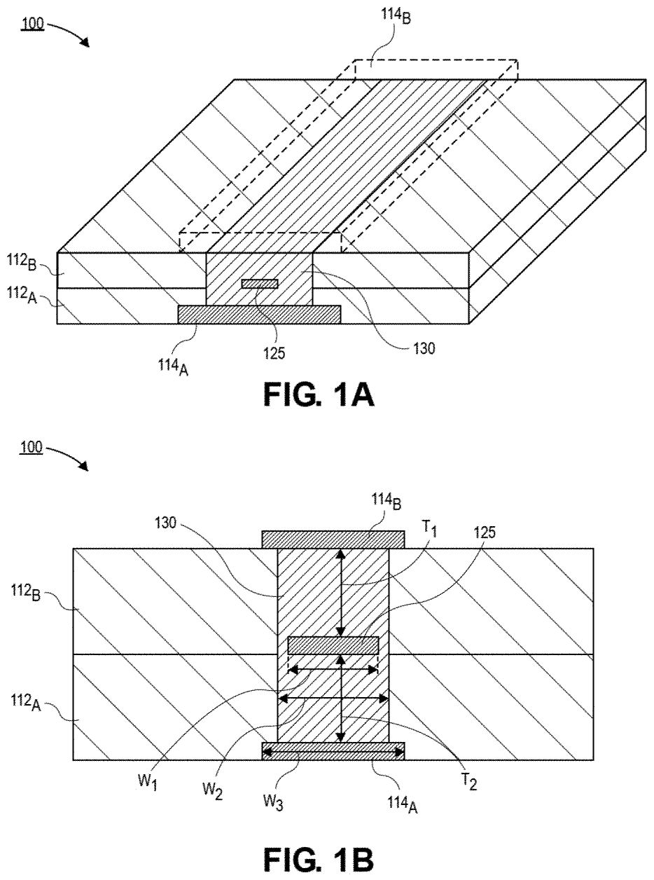

Referring now to FIG. 1A a perspective view illustration of a portion of an electronic package 100 is shown, in accordance with an embodiment. In the illustrated embodiment, a first dielectric layer 112_{A} and a second dielectric layer 112_{E} are shown for simplicity. However, it is to be appreciated that the electronic package 100 may comprise any number of dielectric layers 112. For example, the electronic package 100 may comprise 4 or more layers, 10 or more layers, or 16 or more layers. Dielectric layers 112_{A} and 112_{E} may be the bottommost layers of the electronic package 100, topmost layers of the electronic package 100, or intermediate layers of the electronic package 100.

In an embodiment, the dielectric layers 112_{A} and 112_{E} may be any suitable material layers typical of package substrate manufacturing. For example, the dielectric layers 112_{A} and 112_{E} may comprise a buildup film (BF) or any other suitable dielectric material. In an embodiment, the dielectric layers 112_{A} and 112_{E} may include fillers (e.g., SiO₂ or the like.

In an embodiment, a first metal layer 114_{A} may be embedded in the first dielectric layer 112_{A}. For example, bottom surfaces of the first metal layer 114_{A} may be substantially coplanar with a bottom surface of the first dielectric layer 112_{A}. A second metal layer 114_{E} may be disposed over the second dielectric layer 112_{B}. In some embodiments, a distance between the bottom surface of the first metal layer 114_{A} and a bottom surface of the second metal layer 114_{E} may be substantially equal to the combined thickness of the first dielectric layer 112_{A} and the second dielectric layer 112_{B}.

In an embodiment, a trace 125 may be embedded between the first metal layer 114_{A} and the second metal layer 114_{B}. For example, the trace 125 may be a copper trace of the like. Particularly, the trace 125 may be a trace over which data may be transmitted. In the illustrated embodiment, the trace 125 is the transmission line of a stripline architecture. That is, the first metal layer 114_{A} and the second metal layer 114_{E} may be ground planes.

In an embodiment, a patch 130 is disposed around the trace 125. As shown, the patch 130 extends along the length of the trace 125. In an embodiment, the patch 130 wraps around an entire perimeter of the trace 125. That is, a top surface, a bottom surface, a first sidewall surface, and a second sidewall surface may be in direct contact with the trace 125. In an embodiment, a top surface of the patch 130 may be in direct contact with the second metal layer 114_{E} and a bottom surface of the patch 130 may be in direct contact with the first metal layer 114_{A}.

In an embodiment, the patch 130 has one or more material properties that are different than the material properties of the first dielectric layer 112_{A} and the second dielectric layer 112_{B}. For example, the patch 130 may have mechanical properties, electrical properties, and/or thermal properties that are different than the properties of the first dielectric layer 112_{A} and the second dielectric layer 112_{B}.

In a particular embodiment, the first dielectric layer 112_{A} has a first dielectric constant and the patch 130 has a second dielectric constant that is less than the first dielectric constant. For example, the first dielectric constant may be approximately 4 or greater, and the second dielectric constant may be approximately 4 or less. In an embodiment, the second dielectric constant may be less than 3, less than 2, or less than 1.

In an additional embodiment, the first dielectric layer 112_{A} has a first loss tangent and the patch 130 has a second loss tangent that is lower than the first loss tangent. For example, the first loss tangent may be approximately 0.004 or higher and the second loss tangent may be approximately 0.004 or less (e.g., at a frequency of approximately 10 GHz). In an embodiment the second loss tangent may be approximately 0.002 or less.

It is noted that the selection of materials for the patch 130 is not significantly constrained by manufacturing constraints, mechanical considerations, or the like. This is because the patch 130 only forms a small portion of a given layer of the electronic package 100. That is, the standard buildup materials used for the majority of any given layer in the electronic package 100 dominate the global properties of the electronic package 100. While globally dominated by the buildup materials, the patch materials dominate locally proximate to the trace 125 in order to provide low loss transmission.

Referring now to FIG. 1B, a cross-sectional illustration of a portion of an electronic package 100 is shown, in accordance with an embodiment. In an embodiment, the electronic package 100 comprises a trace 125 that is embedded within a first dielectric layer 112_{A} and a second dielectric layer 112_{B}. Particularly, the trace 125 is directly surrounded by a patch 130. A first metal layer 114_{A} is below the patch 130 and a second metal layer 114_{E} is above the patch 130.

In an embodiment, the trace 125 may have a first width W₁. The first width W₁ may be chosen to provide a desired conduction loss along the trace 125. For example, larger first widths W₁ will typically provide lower conduction losses. In an embodiment, the patch 130 may have a second width W₂. The second width W₂ may be larger than the first width W₁. A larger second width W₂ allows for the patch 130 to completely surround a perimeter of the trace 125. In an embodiment, the first metal layer 114_{A} may have a third width W₃. The third width W₃ may be larger than the second width W₂. Particularly, a third width W₃ that is larger than the second width W₂ allows for the entire patch 130 to land on the first metal layer 114_{A}. Furthermore, as will be described in the process flow below, the larger third width W₃ provides an etchstop layer during the formation of the patch 130.

In the illustrated embodiment, the sidewalls of the patch 130 are substantially vertical. However, it is to be appreciated that the sidewalls of the patch 130 may also be tapered or have any other suitable profile. In an embodiment, the profile of the sidewalls may be dependent on the type of processing used to form the cavity in which the patch 130 is located. For example, lithographic patterning or plasma dry etch patterning of the first and second dielectric layers 112_{A} and 112_{E} may provide substantially vertical sidewalls, whereas laser drilling of the first and second dielectric layers 112_{A} and 112_{B} will provide tapered sidewalls.

In an embodiment, the patch 130 allows for standard dielectric thicknesses to be obtained without sacrificing low loss conditions. For example, a first dielectric thickness T₁ between the top surface of the trace 125 and a bottom surface of the second metal layer 114_{B}, and a second dielectric thickness T₂ between the top surface of the first metal layer 114_{A} and a bottom surface of the trace 125 may be less than 40 μm. In a particular embodiment, the first and second dielectric thicknesses T₁ and T₂ may be between 15 μm and 35 μm. Since the patch 130 allows for excess dielectric thicknesses to be avoided for the high speed routing regions, manufacturing is simplified. For example, copper density is more uniform (since there is no need for skip layers), and the undulation, CTV/BTV, and the like can be more precisely controlled.

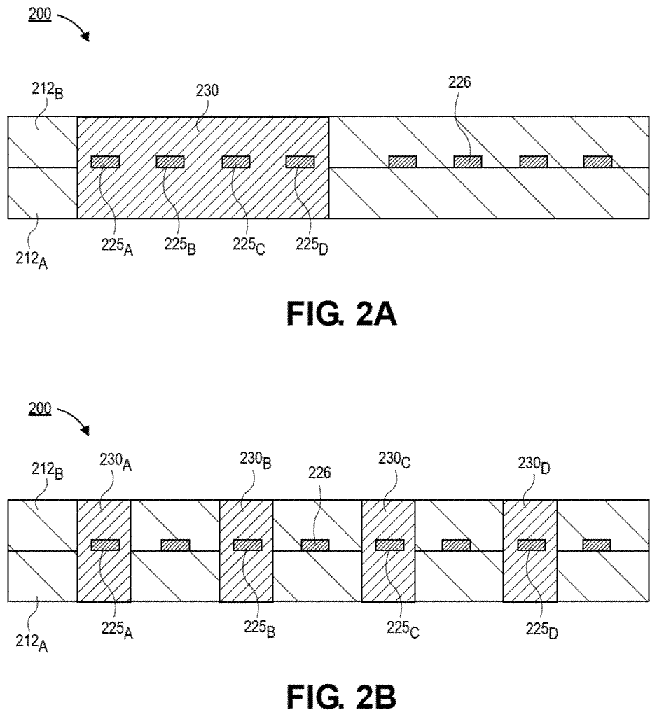

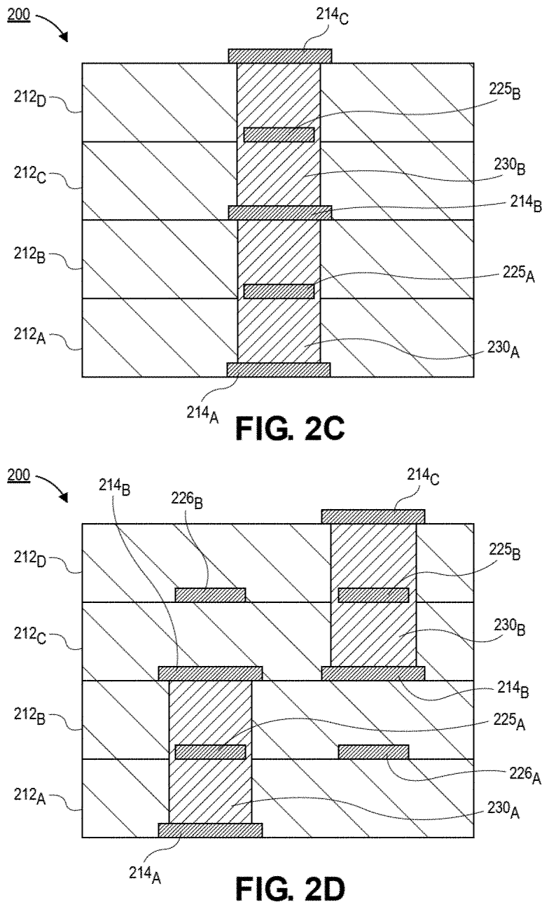

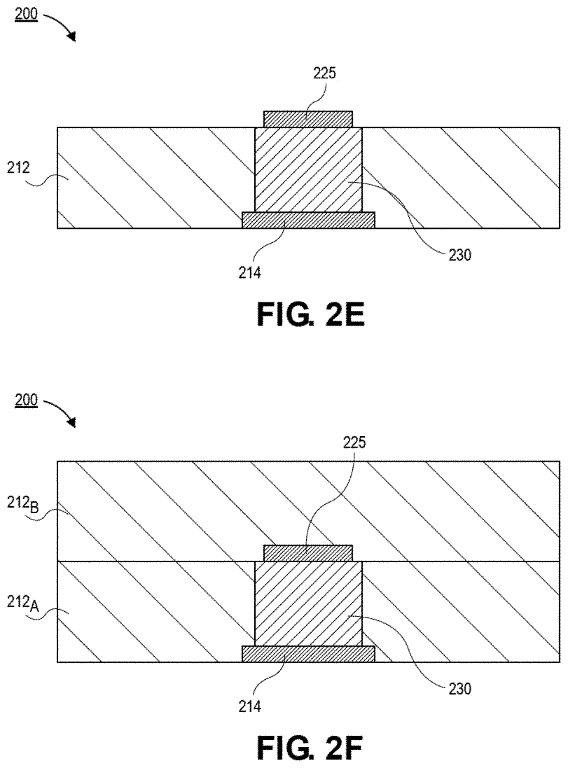

Referring now to FIG. 2A, a cross-sectional illustration of a portion of an electronic package 200 is shown, in accordance with an embodiment. In an embodiment, the electronic package 200 comprises a first dielectric layer 212_{A} and a second dielectric layer 212_{B}. In an embodiment, a first plurality of traces 225_{A-D} and a second plurality of traces 226 are embedded in the electronic package 200. In an embodiment, the first plurality of traces 225_{A-D} may be embedded within a patch 230. In the illustrated embodiment, a single patch 230 may embed more than one trace 225. In an embodiment, the second plurality of traces 226 may be embedded only within the first dielectric layer 212_{A} and the second dielectric layer 212_{B}. That is in a single layer, some of the traces may be embedded in a patch (e.g., traces 225_{A-D}) and some of the traces may not be embedded in a patch (e.g., traces 226).

Referring now to FIG. 2B, a cross-sectional illustration of a portion of an electronic package 200 is shown, in accordance with an embodiment. In an embodiment, the electronic package 200 comprises a first dielectric layer 212_{A} and a second dielectric layer 212_{B}. In an embodiment, a first plurality of traces 225_{A-D} and a second plurality of traces 226 are embedded in the electronic package 200. In an embodiment, the first plurality of traces 225_{A-D} may be embedded within patches 230_{A-D}. In the illustrated embodiment, each of the traces 225_{A-D} are embedded within a different one of the patches 230_{A-D}. In an embodiment, the second plurality of traces 226 may be embedded only within the first dielectric layer 212_{A} and the second dielectric layer 212_{B}. That is in a single layer, some of the traces may be embedded in a patch (e.g., traces 225_{A-D}) and some of the traces may not be embedded in a patch (e.g., traces 226). In an embodiment, traces 226 may be in an alternating pattern with traces 225 that are embedded in a patch 230.

Referring now to FIG. 2C, a cross-sectional illustration of an electronic package 200 is shown, in accordance with an embodiment. In an embodiment, the electronic package 200 may comprise a plurality of dielectric layers 212. For example, four dielectric layers 212_{A-D} are shown in FIG. 2C. In an embodiment, the electronic package 200 may comprise a first metal layer 214_{A}, a second metal layer 214_{B}, and a third metal layer 214_{C}. In an embodiment, traces 225 may be positioned between the metal layers 214. For example, a first trace 225_{A} is between the first metal layer 214_{A} and the second metal layer 214_{B}, and a second trace 225_{B} is between the second metal layer 214_{E} and the third metal layer 214_{C}.

In an embodiment, each of the first trace 225_{A} and the second trace 225_{B} may be embedded in a patch 230. For example, a first patch 230_{A} surrounds the first trace 225_{A} and is positioned between the first metal layer 214_{A} and the second metal layer 214_{E} and, a second patch 230_{B} surrounds the second trace 225_{B} and is positioned between the second metal layer 214_{E} and the third metal layer 214_{C}. In an embodiment, the first patch 230_{A} is aligned over the second patch 230_{B}. For example, sidewalls of the first patch 230_{A} may be substantially aligned to sidewalls of the second patch 230_{B}. In an embodiment, the first patch 230_{A} and the second patch 230_{B} may comprise the same material. In other embodiments, the first patch 230_{A} may comprise a different material than the second patch 230_{B}.

Referring now to FIG. 2D, a cross-sectional illustration of a portion of an electronic package 200 is shown, in accordance with an embodiment. In an embodiment, the electronic package 200 comprises a plurality of dielectric layers 212. For example, four dielectric layers 212_{A-D} are shown in FIG. 2D. In an embodiment, the electronic package 200 may comprise a first metal layer 214_{A}, a second metal layer 214_{B}, and a third metal layer 214_{C}. In the illustrated embodiment, a pair of metal traces are formed in the second dielectric layer 212_{B}. In an embodiment, traces 225 may be positioned between the metal layers 214. For example, a first trace 225_{A} is between the first metal layer 214_{A} and the second metal layer 214_{B}, and a second trace 225_{B} is between the second metal layer 214_{E} and the third metal layer 214_{C}.

In an embodiment, each of the first trace 225_{A} and the second trace 225_{B} may be embedded in a patch 230. For example, a first patch 230_{A} surrounds the first trace 225_{A} and is positioned between the first metal layer 214_{A} and the second metal layer 214_{E} and, and a second patch 230_{B} surrounds the second trace 225_{B} and is positioned between the second metal layer 214_{E} and the third metal layer 214_{C}. In an embodiment, the first patch 230_{A} is offset from the second patch 230_{B}. That is, the region of the electronic package 200 immediately below and/or above the patches 230_{A} and 230_{B} may include standard dielectric material (e.g., dielectric layers 212). For example, a trace 226B embedded in dielectric layer 212_{D} is disposed above the first patch 230_{A}, and a trace 226_{A} embedded in dielectric layer 212_{E} is disposed below the second patch 230_{B}.

Referring now to FIG. 2E, a cross-sectional illustration of an electronic package 200 is shown, in accordance with an additional embodiment. In the electronic package 200, the trace 225 is part of a microstrip routing architecture. That is, there is a single ground reference (e.g., metal layer 214) below the trace 225. In an embodiment, the trace 225 may be separated from the metal layer 214 by a patch 230. In an embodiment, the top surface of the trace 225 may be exposed to air (i.e., not covered). Such an embodiment may be useful when the dielectric layer 212 is the topmost or bottommost layer of the electronic package 200.

Referring now to FIG. 2F, a cross-sectional illustration of an electronic package 200 is shown, in accordance with an additional embodiment. The electronic package 200 in FIG. 2F may be substantially similar to the electronic package 200 in FIG. 2E, with the exception that a second dielectric layer 212_{E} is disposed over the first dielectric layer 212_{A}. Such a configuration may be referred to as a buried microstrip routing configuration since the trace 225 is entirely buried (i.e., covered on all sides).

In an embodiment, the metal layer 214 may be separated from the trace 225 by a patch 230. In an embodiment, the top surface of the trace 225 may be covered by the second dielectric layer 212_{B}. However, it is to be appreciated that in some embodiments, the patch 230 may also extend over the top and sidewall surfaces of the trace 225. That is, the trace 225 may be entirely embedded in the patch 230.

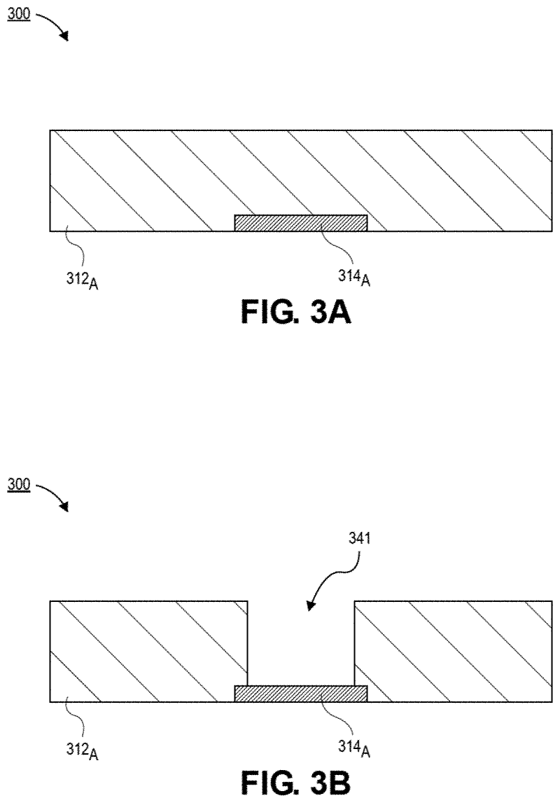

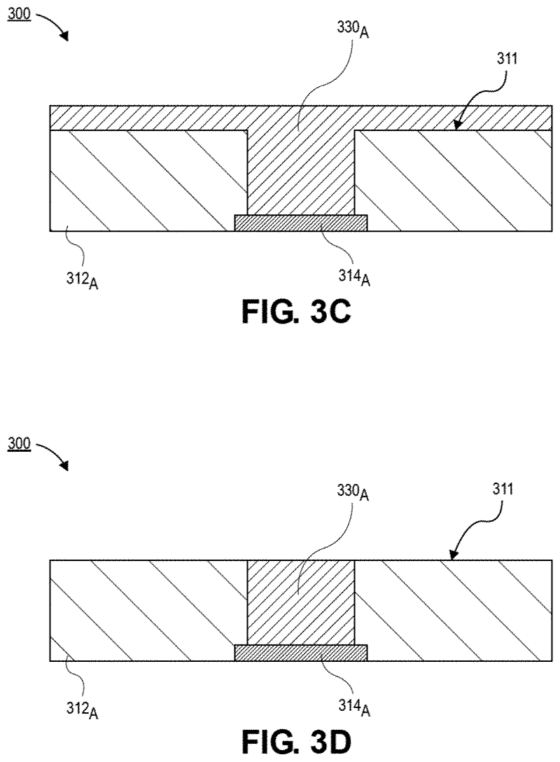

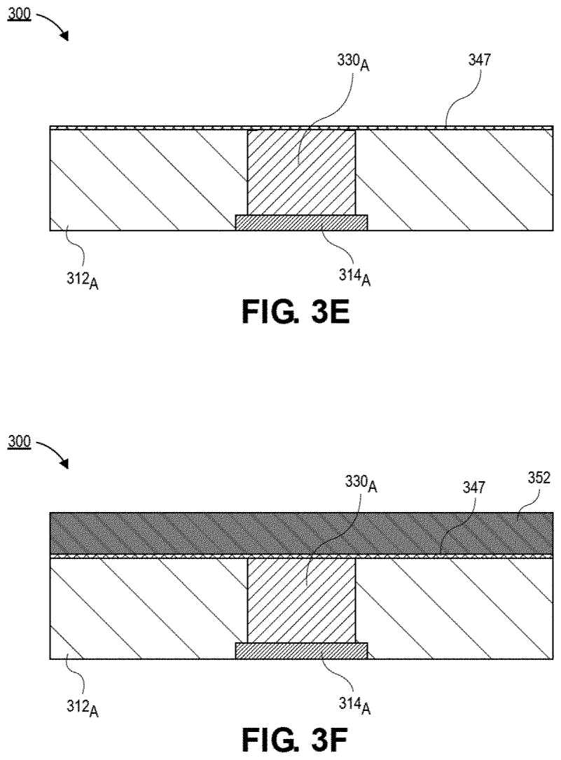

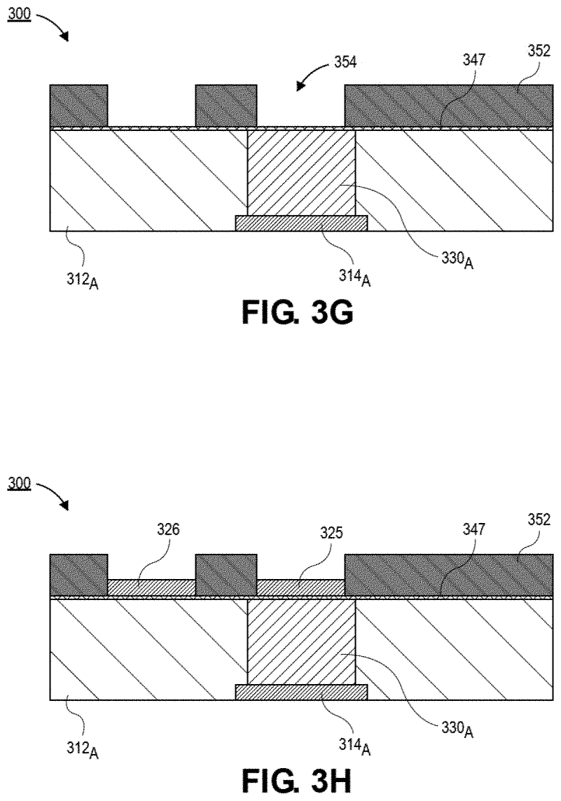

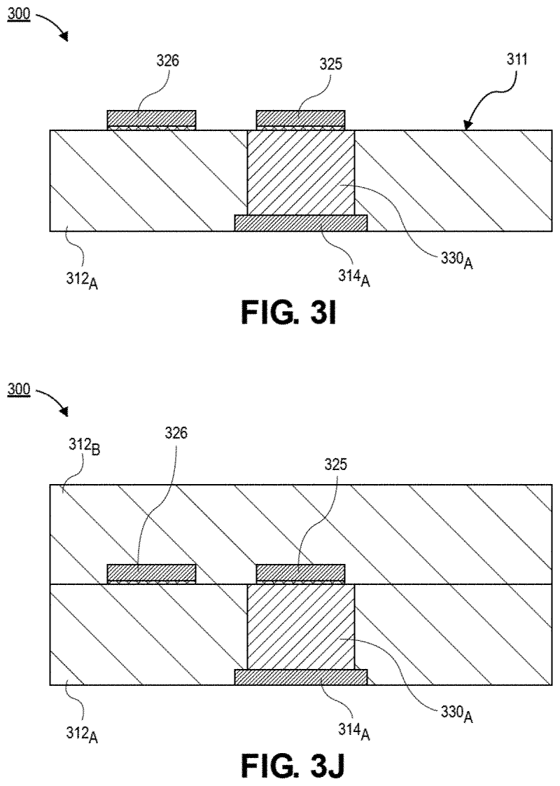

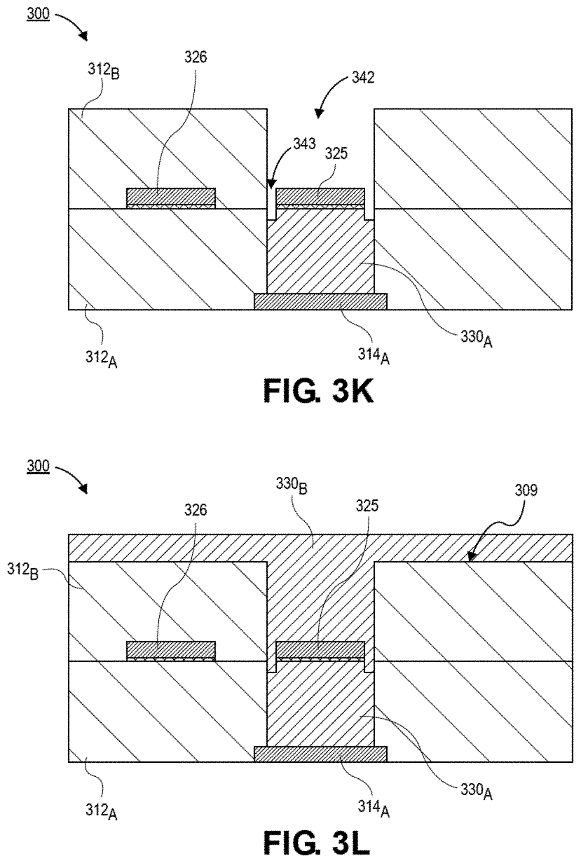

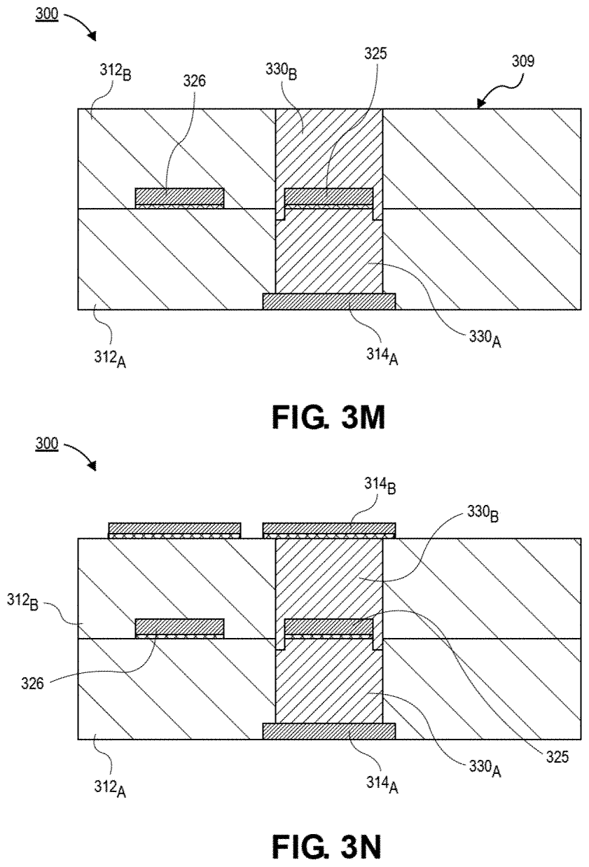

Referring now to FIGS. 3A-3N, a series of cross-sectional illustrations that depict a process for forming an electronic package 300 is shown, in accordance with an embodiment.

Referring now to FIG. 3A, a cross-sectional illustration of an electronic package 300 is shown, in accordance with an embodiment. In an embodiment, the electronic package 300 comprises a first dielectric layer 312_{A}. The first dielectric layer 312_{A} may be any suitable dielectric material typical of electronic packaging substrate. For example, the first dielectric layer 312_{A} may comprise a buildup film or the like. While shown as an isolated layer, it is to be appreciated that the first dielectric layer 312_{A} may be any layer in a stack of dielectric layers used to form the electronic package 300. The first dielectric layer 312_{A} is shown in isolation in order to not obscure embodiments disclosed herein.

In an embodiment, a first metal layer 314_{A} is embedded in the first dielectric layer 312_{A}. The first metal layer 314_{A} may comprise any number of traces, pads, planes or the like. In a particular embodiment, the first metal layer 314_{A} shown in FIG. 3A is a ground plane. In an embodiment the first dielectric layer 312_{A} may have a thickness that is typical of buildup layers in electronic packaging applications. For example, the thickness of the first dielectric layer 312_{A} may be approximately 35 μm or less, or approximately 25 μm or less.

Referring now to FIG. 3B, a cross-sectional illustration of the electronic package 300 after a first opening 341 is formed into the first dielectric layer 312_{A} is shown, in accordance with an embodiment. In an embodiment, the first opening 341 exposes a portion of the first metal layer 314_{A}. In some embodiments, a width of the opening 341 may be less than a width of the first metal layer 314_{A} so that ends of the first metal layer 314_{A} extend past the walls of the first opening 341.

In an embodiment, the first opening 341 may be formed with any suitable subtractive process. In one embodiment, the first opening 341 may be formed using a lithographic process or a plasma dry etch process. In such embodiments, the sidewalls of the first opening 341 may be substantially vertical. In other embodiments, the first opening 341 may be formed using a laser ablation process. In such embodiments, the profile of the sidewalls of the first opening 341 may be tapered.

Referring now to FIG. 3C, a cross-sectional illustration after a first patch layer 330_{A} is disposed into the first opening 341 is shown, in accordance with an embodiment. In an embodiment, the first patch layer 330_{A} may also include overburden that is disposed over a top surface 311 of the first dielectric layer 312_{A}. In an embodiment, the first patch layer 330_{A} may be dispensed with a liquid process or a dry process. In an embodiment, the first patch layer 330_{A} comprises a dielectric material that has different material properties than the first dielectric layer 312_{A}. For example, the first patch layer 330_{A} may have a lower dielectric constant or a lower loss tangent than the first dielectric layer 312_{A}.

Referring now to FIG. 3D, a cross-sectional illustration after the overburden of the first patch layer 330_{A} is removed is shown, in accordance with an embodiment. In an embodiment, the overburden is removed in order to expose the top surface 311 of the first dielectric layer 312_{A}. The overburden may be removed with any suitable process. For example, the overburden may be recessed with a polishing or grinding process. In another embodiment, where the first patch layer 330_{A} is a photo-imageable dielectric (PID), the first patch layer 330_{A} may be lithographically recessed. For example, a blanket exposure of the first patch layer 330_{A} may be implemented followed by a timed developing process. The timed developing process is optimized so that only the top portion of the first patch layer 330_{A} is recessed. That is, the portion of the first patch layer 330_{A} in the first opening 341 remains after the developing process.

In an embodiment, after the first patch layer 330_{A} is recessed to expose the top surface 311 of the first dielectric layer 312_{A}, the first patch layer 330_{A} may be cured. The curing process may comprise a thermal cure, a UV cure, or any other suitable curing process. Curing the remaining portions of the first patch layer 330_{A} may improve mechanical properties of the first patch layer 330_{A}.

Referring now to FIG. 3E, a cross-sectional illustration of the electronic package 300 after a seed layer 347 is disposed over the exposed surfaces is shown, in accordance with an embodiment. The seed layer 347 provides an autocatalytic surface on which an electroless process or sputtering deposition process may be used to plate the next metal layer. In an embodiment, the seed layer 347 is disposed over the top surface of the first patch layer 330_{A} and the first dielectric layer 312_{A}.

Referring now to FIG. 3F, a cross-sectional illustration of the electronic package 300 after a resist layer 352 is disposed over the seed layer 347 is shown, in accordance with an embodiment. The resist layer 352 may be any suitable resist layer common in semiconductor packaging applications.

Referring now to FIG. 3G, a cross-sectional illustration of the electronic package 300 after openings 354 are formed into the resist layer 352 is shown, in accordance with an embodiment. In an embodiment at least one opening 354 is aligned over the first patch layer 330_{A}. Other openings 354 may be positioned over remaining portions of the first dielectric layer 312_{A}.

Referring now to FIG. 3H, a cross-sectional illustration of the electronic package 300 after traces 325 and 326 are disposed in the openings 354 is shown, in accordance with an embodiment. In an embodiment a trace 325 may be disposed over the first patch layer 330_{A} and a trace 326 may be disposed over the first dielectric layer 312_{A}.

Referring now to FIG. 3I, a cross-sectional illustration of the electronic package 300 after the resist is removed is shown, in accordance with an embodiment. In an embodiment, the resist is stripped and exposed portions of the seed layer 347 are etched back. The removal of the seed layer 347 exposes the top surface 311 of the first dielectric layer 312_{A} and a portion of the top surface of the first patch layer 330_{A}.

Referring now to FIG. 3J, a cross-sectional illustration of the electronic package 300 after a second dielectric layer 312E is disposed over the exposed surfaces is shown, in accordance with an embodiment. In an embodiment, the second dielectric layer 312E may be substantially similar to the first dielectric layer 312_{A}. In an embodiment, the second dielectric layer 312E may be disposed with a lamination process.

Referring now to FIG. 3K, a cross-sectional illustration of the electronic package 300 after a second opening 342 is formed through the second dielectric layer 312E is shown, in accordance with an embodiment. In an embodiment, sidewalls of the second opening 342 may be substantially aligned with the sidewalls of the first opening 341. However, it is to be appreciated that the sidewalls of the first opening 341 may also be somewhat misaligned with respect to the sidewalls of the second opening 342 due to tolerances of the systems used to form the first opening 341 and the second opening 342.

In an embodiment, the second opening 342 extends entirely through the second dielectric layer 312E and exposes the trace 325. In some embodiments, where the second opening 342 is wider than the trace 325, recesses 343 into the first patch layer 330_{A} may also be formed since there is no hard etchstop outside the perimeter of the trace 325.

Referring now to FIG. 3L, a cross-sectional illustration of the electronic package 300 after a second patch layer 330_{B} is disposed into the second opening 342 is shown, in accordance with an embodiment. In an embodiment, the second patch layer 330_{B} may also include overburden that is disposed over a top surface 309 of the second dielectric layer 312B. In an embodiment, the second patch layer 330_{B} may be dispensed with a liquid process or a dry process.

In an embodiment, the second patch layer 330_{B} comprises a dielectric material that has different material properties than the first dielectric layer 312_{A} and the second dielectric layer 312B. For example, the second patch layer 330_{B} may have a lower dielectric constant or a lower loss tangent than the first dielectric layer 312_{A}. In an embodiment, the second patch layer 330_{B} may be substantially similar to the first patch layer 330_{A}.

Referring now to FIG. 3M, a cross-sectional illustration after the overburden of the second patch layer 330_{B} is removed is shown, in accordance with an embodiment. In an embodiment, the overburden is removed in order to expose the top surface 309 of the second dielectric layer 312B. The overburden may be removed with any suitable process. For example, the overburden may be recessed with a polishing or grinding process. In another embodiment, where the second patch layer 330_{B} is a photo-imageable dielectric (PID), the second patch layer 330_{B} may be lithographically recessed. For example, a blanket exposure of the second patch layer 330_{B} may be implemented followed by a timed developing process. The timed developing process is optimized so that only the top portion of the second patch layer 330_{B} is recessed. That is, the portion of the second patch layer 330_{B} in the second opening 342 remains after the developing process.

In an embodiment, after the second patch layer 330_{B} is recessed to expose the top surface 309 of the second dielectric layer 312B, the second patch layer 330_{B} may be cured. The curing process may comprise a thermal cure, a UV cure, or any other suitable curing process. Curing the remaining portions of the second patch layer 330_{B} may improve mechanical properties of the second patch layer 330_{B}.

Referring now to FIG. 3N, a cross-sectional illustration of the electronic package 300 after a second metal layer 314_{E} is disposed over the second patch layer 330_{B} is shown, in accordance with an embodiment. In an embodiment, the second metal layer 314_{E} may be disposed with any suitable process, such as SAP or the like.

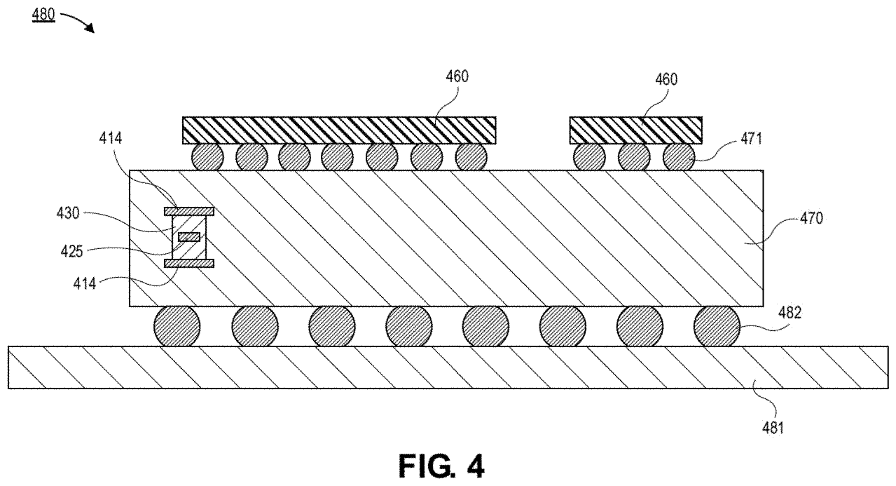

Referring now to FIG. 4, a cross-sectional illustration of an electronic system 480 is shown, in accordance with an embodiment. In an embodiment, the electronic system 480 may comprise a board 481, such as a printed circuit board (PCB) or the like. In an embodiment, one or more package substrates 470 may be electrically coupled to the board 481 by interconnects 482. For example, the interconnects 482 may include bumps, wire bonds, sockets, or any other suitable interconnect architecture. In an embodiment, one or more dies 460 may be electrically coupled to the package substrate 470 by first level interconnects (FLIs) 471.

In an embodiment, the package substrate 470 may comprise a plurality of buildup layers and metal layers. In an embodiment, the buildup layers comprise a first dielectric material. In some embodiments, a trace 425 is embedded in the package substrate 470. The trace 425 may be surrounded by a patch 430. The patch 430 may comprise a second dielectric material that is different than the first dielectric material. In an embodiment, the patch 430 may separate the trace 425 from overlying and/or underlying metal layers 414.

In an embodiment, the electronic system 480 is part of a server system. In an embodiment, the trace 425 provides low loss signaling. Particularly, the trace 425 includes a width that reduces conductor losses, and the patch 430 provides a dielectric constant that allows for impedance matching without needing to alter the dielectric thickness. Accordingly, high performance electronic systems 480 with manufacturable process flows are provided in accordance with embodiments disclosed herein.

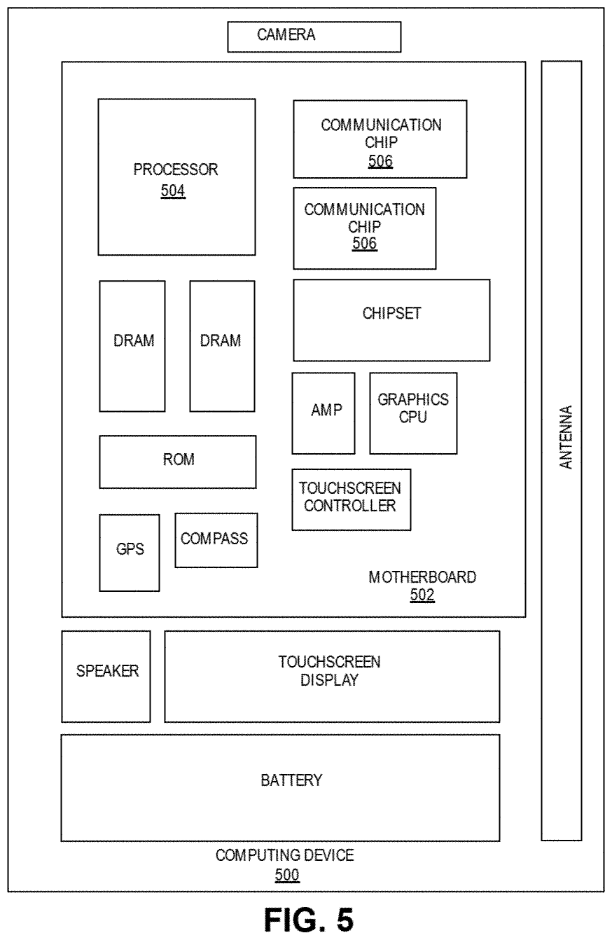

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor 504 may be part of an electronic package that comprises a package substrate with a first dielectric material and a patch of a second dielectric material surrounding a signaling trace, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip 506 may be part of an electronic package that comprises a package substrate with a first dielectric material and a patch of a second dielectric material surrounding a signaling trace, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a substrate comprising a first dielectric material; a first trace embedded in the substrate; and a patch in direct contact with the first trace, wherein the patch comprises a second dielectric material that is different than the first dielectric material.

Example 2: the package substrate of Example 1, wherein the patch is in direct contact with a first surface and a second surface of the first trace, wherein the first surface is opposite the second surface.

Example 3: the package substrate of Example 2, wherein the patch is in direct contact with an entire perimeter of the first trace.

Example 4: the package substrate of Examples 1-3, wherein a length of the first trace is substantially equal to a length of the patch.

Example 5: the package substrate of Examples 1-4, further comprising: a second trace over the first trace; and a third trace under the first trace.

Example 6: the package substrate of Example 5, wherein the patch is in direct contact with the second trace and the third trace.

Example 7: the package substrate of Examples 1-4, further comprising: a second trace adjacent to the first trace, wherein the patch surrounds the first trace and the second trace.

Example 8: the package substrate of Examples 1-7, wherein the first dielectric material has a first dielectric constant and the second dielectric material has a second dielectric constant that is lower than the first dielectric constant.

Example 9: the package substrate of Example 8, wherein the second dielectric constant is less than 3.

Example 10: the package substrate of Examples 1-9, wherein the patch locally modifies one or more of a mechanical property, an electrical property, and a thermal property of the package substrate.

Example 11: an electronic package, comprising: a die; a package substrate electrically coupled to the die, wherein the package substrate comprises: a first layer, wherein the first layer comprises a first dielectric material; a first trace in the first layer, wherein the first trace is surrounded by a patch, wherein the patch is a second dielectric material that is different than the first dielectric material.

Example 12: the electronic package of Example 11, wherein the first trace is for propagating signals in a microstrip.

Example 13: the electronic package of Example 11, wherein the first trace is for propagating signals in a stripline.

Example 14: the electronic package of Examples 11-13, further comprising: a second trace in the first layer, wherein the second trace is surrounded by the first dielectric material.

Example 15: the electronic package of Examples 11-13, further comprising: a second trace in the first layer, wherein the second trace is surrounded by the patch.

Example 16: the electronic package of Examples 11-15, wherein the package substrate further comprises: a second layer over the first layer, wherein the second layer comprises the first dielectric material; and a third layer below the first layer, wherein the third layer comprises the first dielectric material.

Example 17: the electronic package of Example 16, wherein the patch extends into the second layer and the third layer.

Example 18: the electronic package of Examples 11-13, 16, or 17, further comprising: a second trace, wherein the second trace is surrounded by a second patch that is different than the patch that surrounds the first trace.

Example 19: the electronic package of Examples 11-18, wherein the first dielectric material has a first dielectric constant, and wherein the second dielectric material has a second dielectric constant that is less than the first dielectric constant.

Example 20: a method for forming a package substrate, comprising: forming a metal layer embedded in a first dielectric layer; forming a first opening over the metal layer through the first dielectric layer; disposing a first patch layer in the first opening, wherein the first dielectric layer is different than the first patch layer; disposing a trace above the metal layer and in contact with the first patch layer; disposing a second dielectric layer over the first dielectric layer and the trace; forming a second opening through the second dielectric layer, wherein the second opening exposes the trace; and disposing a second patch layer in the second opening, wherein the second patch layer is the same material as the first patch layer.

Example 21: the method of Example 20, wherein the first patch layer is a photo-imageable dielectric material.

Example 22: the method of Example 21, wherein disposing the first patch layer in the first opening, comprises: dispensing the first patch layer so that the first patch layer fills the first opening and covers a top surface of the first dielectric layer; exposing the first patch layer; developing the first patch layer with a timed process that removes overburden over the top surface of the first dielectric layer.

Example 23: the method of Examples 20-22, wherein forming the second opening comprises: removing a portion of the second dielectric layer; and removing a portion of the first patch layer.

Example 24: the method of Examples 20-23, wherein the first patch layer comprises a dielectric constant that is less than a dielectric constant of the first dielectric layer.

Example 25: the method of Examples 20-24, further comprising: disposing a second metal layer over the trace to form a stripline architecture, wherein the trace is separated from the first metal layer by the first patch layer, and wherein the trace is separated from the second metal layer by the second patch layer.

What is claimed is:

1. A package substrate, comprising:
a substrate comprising a first dielectric material;
a first trace embedded in the substrate; and
a patch in direct contact with the first trace, wherein the patch comprises a second dielectric material that is different than the first dielectric material.

2. The package substrate of claim 1, wherein the patch is in direct contact with a first surface and a second surface of the first trace, wherein the first surface is opposite the second surface.

3. The package substrate of claim 2, wherein the patch is in direct contact with an entire perimeter of the first trace.

4. The package substrate of claim 1, wherein a length of the first trace is substantially equal to a length of the patch.

5. The package substrate of claim 1, further comprising:
a second trace over the first trace; and
a third trace under the first trace.

6. The package substrate of claim 5, wherein the patch is in direct contact with the second trace and the third trace.

7. The package substrate of claim 1, further comprising:
a second trace adjacent to the first trace, wherein the patch surrounds the first trace and the second trace.

8. The package substrate of claim 1, wherein the first dielectric material has a first dielectric constant and the second dielectric material has a second dielectric constant that is lower than the first dielectric constant.

9. The package substrate of claim 8, wherein the second dielectric constant is less than 3.

10. The package substrate of claim 1, wherein the patch locally modifies one or more of a mechanical property, an electrical property, and a thermal property of the package substrate.

11. An electronic package, comprising:
a die;
a package substrate electrically coupled to the die, wherein the package substrate comprises:
a first layer, wherein the first layer comprises a first dielectric material;
a first trace in the first layer, wherein the first trace is surrounded by a patch, wherein the patch is a second dielectric material that is different than the first dielectric material.

12. The electronic package of claim 11, wherein the first trace is for propagating signals in a microstrip.

13. The electronic package of claim 11, wherein the first trace is for propagating signals in a stripline.

14. The electronic package of claim 11, further comprising:
a second trace in the first layer, wherein the second trace is surrounded by the first dielectric material.

15. The electronic package of claim 11, further comprising:
a second trace in the first layer, wherein the second trace is surrounded by the patch.

16. The electronic package of claim 11, wherein the package substrate further comprises:
a second layer over the first layer, wherein the second layer comprises the first dielectric material; and
a third layer below the first layer, wherein the third layer comprises the first dielectric material.

17. The electronic package of claim 16, wherein the patch extends into the second layer and the third layer.

18. The electronic package of claim 11, further comprising:
a second trace, wherein the second trace is surrounded by a second patch that is different than the patch that surrounds the first trace.

19. The electronic package of claim 11, wherein the first dielectric material has a first dielectric constant, and wherein the second dielectric material has a second dielectric constant that is less than the first dielectric constant.

20. A method for forming a package substrate, comprising:
forming a metal layer embedded in a first dielectric layer;
forming a first opening over the metal layer through the first dielectric layer;
disposing a first patch layer in the first opening, wherein the first dielectric layer is different than the first patch layer;
disposing a trace above the metal layer and in contact with the first patch layer;
disposing a second dielectric layer over the first dielectric layer and the trace;
forming a second opening through the second dielectric layer, wherein the second opening exposes the trace; and
disposing a second patch layer in the second opening, wherein the second patch layer is the same material as the first patch layer.

21. The method of claim 20, wherein the first patch layer is a photo-imageable dielectric material.

22. The method of claim 21, wherein disposing the first patch layer in the first opening, comprises:
dispensing the first patch layer so that the first patch layer fills the first opening and covers a top surface of the first dielectric layer;
exposing the first patch layer;
developing the first patch layer with a timed process that removes overburden over the top surface of the first dielectric layer.

23. The method of claim 20, wherein forming the second opening comprises:
removing a portion of the second dielectric layer; and
removing a portion of the first patch layer.

24. The method of claim 20, wherein the first patch layer comprises a dielectric constant that is less than a dielectric constant of the first dielectric layer.

25. The method of claim 20, further comprising:
disposing a second metal layer over the trace to form a stripline architecture, wherein the trace is separated from the first metal layer by the first patch layer, and wherein the trace is separated from the second metal layer by the second patch layer.
